(19) United States
(12) Patent Application Publication
(10) Pub. No.: US 2026/0052717 A1
(43) Pub. Date: Feb. 19, 2026

(54) YTTRIUM-Doped III-Nitride Semiconductor Devices

(71) Applicant: The Regents of the University of Michigan, Ann Arbor, MI (US)

(72) Inventors: Zetian MI, Ann Arbor, MI (US); Ding WANG, Ann Arbor, MI (US); Danhao WANG, Ann Arbor, MI (US); Shubham MONDAL, Ann Arbor, MI (US)

(21) Appl. No.: 18/749,135

(22) Filed: Jun. 20, 2024

Related U.S. Application Data
(60) Provisional application No. 63/522,033, filed on Jun. 20, 2023.

(51) Int. Cl. H10D 30/47; H10D 30/69; H10D 62/40; H10D 62/824; H10D 64/68

(52) U.S. Cl. CPC H10D 30/475; H10D 30/701; H10D 62/40; H10D 62/824; H10D 64/689; H10D 64/691

(57) ABSTRACT

A device includes a substrate and a heterostructure supported by the substrate. The heterostructure includes an alloy layer including an alloy of a III-nitride material and a III-nitride semiconductor layer adjacent the alloy layer. The alloy includes yttrium. A heterointerface between the alloy layer and the III-nitride semiconductor layer has a Type-I band alignment.

### CROSS-REFERENCE TO RELATED APPLICATION

This application claims the benefit of U.S. provisional application entitled “Yttrium-Doped III-Nitride Semiconductor Devices,” filed Jun. 20, 2023, and assigned Ser. No. 63/522,033, the entire disclosure of which is hereby expressly incorporated by reference.

### STATEMENT REGARDING FEDERALLY SPONSORED RESEARCH OR DEVELOPMENT

This invention was made with government support under Contract No. W911 NF-22-2-0176 awarded by the U.S. Army Research Office and Contracts Nos. HR0011-22-C-0087 and HR0011-22-2-0024 awarded by the U.S. Department of Defense, Defense Advanced Research Projects Agency. The government has certain rights in the invention.

### BACKGROUND OF THE DISCLOSURE

### Field of the Disclosure

The disclosure relates generally to Group III-nitride materials and heterostructures.

### Brief Description of Related Technology

III-nitride semiconductor heterostructures and nanostructures have become a prominent focus in the semiconductor community due to their exceptional properties and broad range of applications. To fully exploit the potential of III-nitride semiconductor heterostructures for next-generation optoelectronic and electronic systems, the incorporation of rare earth elements has been explored. One successful strategy has incorporated the rare-earth Sc element into the III-nitride wurtzite lattice, which imparts unique properties, such as ferroelectric behavior, tunable spontaneous polarization coefficients, and significantly enhanced piezoelectric and linear and nonlinear optical properties. For instance, ScAlN has been predicted to have three times larger spontaneous polarization coefficients than AlN, and studies have shown an approximately four times larger piezoelectric coefficient d₃₃ and an order of magnitude higher optical nonlinearity than AlN. Most recently, unique non-oxide ferroelectric properties have been observed in both sputtered and epitaxy-grown ScAlN, with a coercive field of 3-6 MV/cm, remnant polarization of 120-150 μC/cm², and a retention time beyond 105 seconds. These distinctive characteristics, coupled with the tunable large bandgap of ScAlN, make ScAlN a leading candidate for multifunctional power electronics, ferroelectric memory, reconfigurable piezo-electronics, and advanced optoelectronics.

The demonstration of ferroelectricity in (Sc)-alloyed wurtzite nitrides has expanded the potential applications of III-nitrides even further. With their polar structure, switchable electrical polarization, and scalability, Sc-alloyed III-nitrides have shown great promise for applications in low-power nonvolatile memories, self-powered sensing, energy harvesting and storage mechanisms. The origin of ferroelectricity in Sc-alloyed III-nitrides can be attributed to the flattening of the potential energy landscape towards the non-polar layered hexagonal phase, resulting from the distortion of the wurtzite crystal structure.

Initial studies of Sc-alloyed III-nitrides were limited to sputter deposition, which often yield polycrystalline films with textured surfaces. Recent advances in epitaxial growth using molecular beam epitaxy (MBE) have allowed for the demonstration of ferroelectricity in single crystalline ScAlN and ScGaN thin films. These high-quality ferroelectric thin films have enabled the scaling of the films down to about 5 nm and the development of various ferroelectric devices, including ScAlN/GaN heterostructure memories, ScAlN/GaN HEMT devices, and ScAlN-based self-powered photodetectors

Despite its significant potential, the cost of Sc makes ScAlN less attractive for practical applications.

### SUMMARY OF THE DISCLOSURE

In accordance with one aspect of the disclosure, a device includes a substrate and a heterostructure supported by the substrate. The heterostructure includes an alloy layer including an alloy of a III-nitride material, and a III-nitride semiconductor layer adjacent the alloy layer. The alloy includes yttrium. A heterointerface between the alloy layer and the III-nitride semiconductor layer has a Type-I band alignment.

In accordance with another aspect of the disclosure, a device includes a substrate and a heterostructure supported by the substrate. The heterostructure includes an alloy layer including an alloy of a III-nitride material. The alloy includes yttrium. The alloy has an yttrium composition of about 10% or less.

In accordance with yet another aspect of the disclosure, a high electron mobility transistor (HEMT) device includes a substrate and a heterostructure supported by the substrate. The heterostructure includes a barrier layer including an alloy of a III-nitride material, the alloy including yttrium, a channel layer positioned relative to the barrier layer to define a junction at which a charge carrier sheet is disposed, the channel layer including a first III-nitride semiconductor material, and an insertion layer disposed between the barrier layer and the channel layer, the insertion layer including a second III-nitride semiconductor material. A band gap difference between the first and second III-nitride semiconductor materials enhances mobility of the charge carrier sheet.

In connection with any one of the aforementioned aspects, the devices and/or methods described herein may alternatively or additionally include or involve any combination of one or more of the following aspects or features. The alloy layer is monocrystalline. The alloy layer is wurtzite phase. The alloy layer is ferroelectric. The alloy layer is positioned in the heterostructure as a gate dielectric layer. The alloy layer is positioned in the heterostructure as a barrier layer. The III-nitride semiconductor layer includes GaN. The alloy has an yttrium composition of about 10% or less. The alloy has an yttrium composition between about 7% and about 10%. The ferroelectric III-nitride alloy layer includes YAlN. The alloy layer is supported by the III-nitride semiconductor layer. The III-nitride semiconductor layer includes AlN. The heterostructure further includes a III-nitride semiconductor cap layer adjacent the barrier layer. The second III-nitride semiconductor material includes AlN.

### BRIEF DESCRIPTION OF THE DRAWING FIGURES

For a more complete understanding of the disclosure, reference should be made to the following detailed description and accompanying drawing figures, in which like reference numerals identify like elements in the figures.

FIG. 1 depicts (a) schematic illustrations of a GaN film (sample A), a 5 nm Y_{0.07}Al_{0.93}N/GaN film (sample B), and a 60 nm Y_{0.07}Al_{0.93}N/GaN film (sample C) on GaN/sapphire substrates, (b) RHEED patterns of three samples captured along [112̅0] after growth, (c) XRD (0002) 2θ-ω measurements of the three samples, and (d) XRD (0002) rocking curve measurements of sample C.

FIG. 2 depicts (a) a cross-sectional high resolution HAADF-STEM image of a Y_{0.07}Al_{0.93}N/GaN heterointerface in accordance with one example, (b, c) nano-beam electron diffraction patterns acquired along the [112̅0] zone-axis for (b) the Y_{0.07}Al_{0.93}N layer and (c) the GaN layer, and (d) corresponding element distribution of the Y_{0.07}Al_{0.93}N/GaN interface.

FIG. 3 depicts (a) a graphical plot showing the core level of Ga 3d and valence band spectra of a GaN layer (e.g., of a YAlN/GaN heterointerface in accordance with one example), (b) a graphical plot showing the core level of Al 2p and valence band spectra of the Y_{0.07}Al_{0.93}N layer (e.g., of the YAlN/GaN heterointerface), (c) a graphical plot showing the core level of Al 2p and Ga 3d spectra of the Y_{0.07}Al_{0.93}N/GaN heterojunction, (d) a Tauc plot of YaIN, and (e) a schematic diagram of the band alignment of the Y_{0.07}Al_{0.93}N/GaN heterojunction, along with the band edge alignment between InN, GaN and Sc_{0.18}Al_{0.82}N.

FIG. 4 depicts schematic illustrations of (a) device configuration and corresponding (b) band structure of YAlN based HEMT structure in accordance with one example, (c) a graphical plot showing a comparison of the room temperature transport properties of the YAlN/AlN/GaN HEMT structure with previously reported rare earth element-containing nitride epitaxial heterostructures, and graphical plots of temperature-dependent (d) sheet carrier density, (e) Hall mobility, and (f) sheet resistance of example YAlN/AlN/GaN heterostructures.

FIG. 5 depicts material and other characterizations of an example YAlN/GaN heterostructures grown by MBE, including (a) a schematic illustration of a YAlN/n-GaN heterostructure in accordance with one example, (b) RHEED patterns along [112̅0] and [101̅0]azimuths after YAlN growth, (c) a 4×4 μm² AFM image of the YAlN surface, with R.M.S roughness of 0.8 nm, (d) a graphical plot of (0002) plane XRD 2θ-ω scans, with FWHM of the XRC scan corresponding to YAlN being 324 arcsec, and (e) a graphical plot of (101̅2) plane XRD φ scans showing perfect epitaxial registry of YAlN with the underlying wurtzite GaN.

FIG. 6 depicts TEM analysis of an example YAlN thin film grown on n-GaN by MBE, including (a) a cross-sectional TEM image of the YAlN/GaN heterostructure, (b) a magnified HAADF-STEM image showing the well-aligned lattice registry and sharp interface, (c) NBED patterns for YAlN and GaN along the [112̅0] zone-axis showing clear wurtzite crystal structure, and (d) EDS mapping of the heterostructure capped with Ti electrode layer.

FIG. 7 depicts graphical plots of (a) J-E loops with different maximum biasing voltages, (b) corresponding P-E loops for an example YAlN thin film with an electrode diameter of 20 μm (non-switching currents were subtracted), and (c) voltage-dependent PUND measurement results using triangular voltage profile, showing polarization saturation in both directions.

FIG. 8 depicts graphical plots of (a) unipolar C-V loops showing the switching of polarity in example YAlN layers (switching half loops are only observed after poling at the other direction), and (b) frequency dependent C-V loops, in which the butterfly shaped C-V hysteresis loops confirm the ferroelectric switching in the YAlN thin films.

FIG. 9 depicts etching results showing the polarization switching of example YAlN films, including (a) an SEM image of the as-grown YAlN surface, (b) a flow diagram of processing steps for the wet-etching measurements, and (c, d) etching results showing that the switched region beneath the electrode can be selectively removed by TMAH, while the back-switched region, i.e., the region has been switched then switched back, is almost unaffected (the scale bar is 500 nm).

FIG. 10 is a flow diagram of a method of fabricating a YAlN-based heterostructure in accordance with one example.

FIGS. 11A and 11B depict cross-sectional, schematic views of ferroelectric field effect transistor (FeFET) memory cells with a single-crystal, or monocrystalline, layer of an alloy of a III-nitride material (e.g., YₓA₁₋ₓN) between a gate electrode and a source-drain conduction region to provide a reversible electrical state in accordance with two examples.

FIGS. 12A and 12B are cross-sectional, schematic views of ferroelectric tunnel junction (FTJ) memory devices with a monocrystalline layer of an alloy of a III-nitride material (e.g., YₓA₁₋ₓN) in accordance with two examples.

FIGS. 13A and 13B are cross-sectional, schematic views of metal-polar and N-polar ferroelectric high electron mobility transistor (Fe-HEMT) devices, respectively, each having a monocrystalline layer of an alloy of a III-nitride material (e.g., YₓA₁₋ₓN) in accordance with two examples.

FIGS. 14A and 14B are cross-sectional, schematic views of a reconfigurable Fe-HEMT device having a monocrystalline layer of an alloy of a III-nitride material (e.g., YₓA₁₋ₓN) in accordance with one example, in which the polarization direction, indicated by green arrows, of a ferroelectric layer under a gate can be reconfigured by applying an electric field beyond the coercive field.

FIG. 15 is a cross-sectional, schematic view of a ferroelectric photovoltaic device with a monocrystalline layer of an alloy of a III-nitride material (e.g., YₓA₁₋ₓN) as a photon absorption layer in accordance with one example.

FIGS. 16A and 16B are cross-sectional, schematic views of ferroelectric photovoltaic devices, each having a monocrystalline layer of an alloy of a III-nitride material (e.g., YₓA₁₋ₓN) to provide one or more ferroelectric regions, and further having a monocrystalline layer of a III-nitride material as a photon absorption layer in accordance with two examples.

FIG. 17 is a cross-sectional, schematic view of a lateral homojunction device with a monocrystalline layer of an alloy of a III-nitride material (e.g., YₓA₁₋ₓN) to provide one or more ferroelectric regions in accordance with one example.

The embodiments of the disclosed devices may assume various forms. Specific embodiments are illustrated in the drawing and hereafter described with the understanding that the disclosure is intended to be illustrative. The disclosure is not intended to limit the invention to the specific embodiments described and illustrated herein.

### DETAILED DESCRIPTION OF THE DISCLOSURE

Devices and methods involving growth of epitaxial (e.g., fully epitaxial) alloys of III-nitride materials are described. In some cases, the alloys are ferroelectric. The disclosed devices and methods involve the incorporation of yttrium (Y) into the wurtzite crystal structure of the III-nitride material. Various heterostructures with one or more III-nitride layers are described.

Yttrium (Y), which belongs to the same group Ill transition metals as Sc, is a more cost-effective option for alloying with III-nitride materials. Y has similar electronic outer shell configuration to Sc and can impart similar properties to III-nitride materials when alloyed. Additionally, both Sc and Y exhibit larger lattice constants than GaN when crystallizing in a hexagonal lattice, which allows both Sc and Y hexagonal nitrides to be lattice-matched to GaN when alloyed with AlN (which has a smaller lattice constant than GaN) at a desired composition. These characteristics presents opportunities for YAlN to integrate various functionalities into III-nitride electronics and optoelectronics, including, for instance, adding intelligence to nitride-based devices.

The YAlN-based heterostructures described herein may be useful in various applications, including, for instance, multifunctional power electronics, ferroelectric memory, reconfigurable piezo-electronics, and advanced optoelectronics. Examples of YAlN-based HEMT devices described herein take advantage of the band alignment relationship and transport characteristics of a YAlN-based heterojunction (e.g., Y_{0.07}Al_{0.93}N based heterojunction), which have remained unknown to date.

Described herein are examples of YAlN-based heterostructures exhibiting a Type-I band alignment. The examples include a YAlN based high-electron-mobility transistor (HEMT) structure. Measurements revealed a type-I band alignment for the Y_{0.07}Al_{0.93}N/GaN heterojunction, with a valence band offset of −0.1 eV and conduction band offset of 2.2 eV. Transport properties of an example Y_{0.07}Al_{0.93}N/AlN/GaN heterojunction-based HEMT included a mobility of 1000 cm²/Vs, a sheet electron concentration of 4.2×10¹³ cm², and a sheet resistance of 148Ω/□, at room temperature, which are among the best values reported for rare earth element-containing nitride epitaxial heterostructures. Detailed temperature-dependent Hall measurements identified the dominant factors affecting transport properties at different temperature ranges. The excellent electrical characteristics, non-oxide ferroelectric properties, and compatibility with mainstream semiconductor technology, establish the YAlN-based heterostructures as useful in a wide variety of devices, including, for instance, multifunctional HEMT devices.

Although described in connection with examples of epitaxially grown YₓAl₁₋ₓN layers, the disclosed methods and devices may be applied to a wide variety of III-nitride alloys. The disclosed methods and devices may thus include or involve the incorporation of scandium into other III-nitride wurtzite structures. For instance, the disclosed methods and devices may include or involve one or more epitaxially grown YₓAl_{y}Ga_{1-x-y}N layers, YₓGa₁₋ₓN layers, or YₓIn₁₋ₓN layers. The configuration, construction, fabrication, and other characteristics of the heterostructures may also vary from the examples described. For instance, the heterostructures may include any number of epitaxially grown layers of ferroelectric and non-ferroelectric nature. The disclosed methods and devices are not limited to III-nitride alloys including scandium. For instance, the III-nitride alloys may include additional group IIIB elements, such as scandium (Sc) and lanthanum (La).

Although the disclosed methods are described in connection with MBE growth procedures, additional or alternative non-sputtered epitaxial growth procedures may be used. For instance, metal-organic chemical vapor deposition (MOCVD), hydride vapor phase epitaxy (HVPE), atomic layer deposition (ALD), and atomic layer epitaxy (ALE) growth procedures may be used. Still other procedures may be used, including, for instance, pulsed laser deposition procedures.

The band alignment and transport characteristics of an example Y_{0.07}Al_{0.93}N/GaN heterojunction and an example Y_{0.07}Al_{0.93}N-based HEMT structure were acquired using high-resolution X-ray photoelectron spectroscopy (HR-XPS) and temperature-dependent Hall measurements, respectively. The surface and interface quality of the heterojunction were assessed using in situ reflection high-energy electron diffraction (RHEED), high-resolution transmission electron microscopy, and corresponding energy-dispersive X-ray spectroscopy (EDS) mapping. HR-XPS demonstrated a type-I alignment of the Y_{0.07}Al_{0.93}N/GaN heterojunction, with a valence band offset of −0.1 eV and conduction band offset of 2.2 eV.

The band alignment information is used to provide an example Y_{0.07}Al_{0.93}N/AlN/GaN heterojunction-based high-electron-mobility transistor (HEMT) structure. At room temperature, a mobility of 1000 cm²/Vs, a sheet electron concentration of 4.2×10¹³ cm², and a sheet resistance of 148Ω/□ (or Ω/sq), were achieved, which are among the best values reported for rare earth element-containing nitride epitaxial heterostructures. Temperature-dependent Hall measurements unveiled the dominant factors influencing transport properties across different temperature regions. The outstanding electrical characteristics, combined with appealing non-oxide ferroelectrics and compatibility with mainstream semiconductor technology, may be useful in connection multi-functional HEMT and other devices.

Example YAlN films were synthesized using a Veeco GENxplor molecular beam epitaxy (MBE) system, equipped with a radio frequency (RF) plasma-assisted nitrogen source and an integrated Telemark electron beam evaporator for yttrium (Y) deposition. To maintain a consistent yttrium composition of approximately 0.07, the Y deposition rate was held constant, as confirmed by energy dispersive X-ray spectroscopy (EDS) analysis performed in a scanning electron microscope (SEM).

All of the examples were prepared on semi-insulating gallium nitride (GaN)/sapphire templates. Initially, a 100 nm GaN layer was grown under gallium-rich conditions at a substrate temperature of 580° C. (as measured by a thermocouple) with a nitrogen flow of 0.3 sccm and plasma power of 350 V. Subsequently, the YAlN layer was deposited under nitrogen-rich conditions at a slightly reduced temperature of 500° C. and a growth rate of approximately 2 nm/min. The X-ray diffraction (XRD) was measured using a Rigaku SmartLab diffractometer with Cu Kα line (λ=1.5418 Å). Transmission electron microscopy (TEM) was carried out using a Thermo Fisher Scientific Spectra 300 probe-corrected STEM equipped with a Dual-X EDS system and operated at 300 kV. High-angle annular dark-field (HAADF) images were collected in a range of 62-200 mrad with a convergence angle of 22 mrad. The TEM specimen was prepared using a Thermo Fisher Scientific Helios G4 UXe focus ion beam (FIB). The HR-XPS measurements were conducted on a Kratos Axis Ultra XPS instrument equipped with an Al Kα source (hv=1486.6 eV). The binding energy scale of all HR-XPS results was calibrated by referencing C1s peak (284.8 eV). Temperature-dependent Hall effect measurements were performed in a Quantum Design physical property measurement system (PPMS) and the sample was configured in the standard van der Pauw geometry. The examples were held at each temperature for 30 minutes prior to measurement to allow for adequate temperature stability. Sheet resistance and Hall effect measurements were performed using a Keithley 2450 and a source current of 1 mA. For the Hall effect measurement, the magnetic field was swept from +1 T to −1 T in increments of 20 mT.

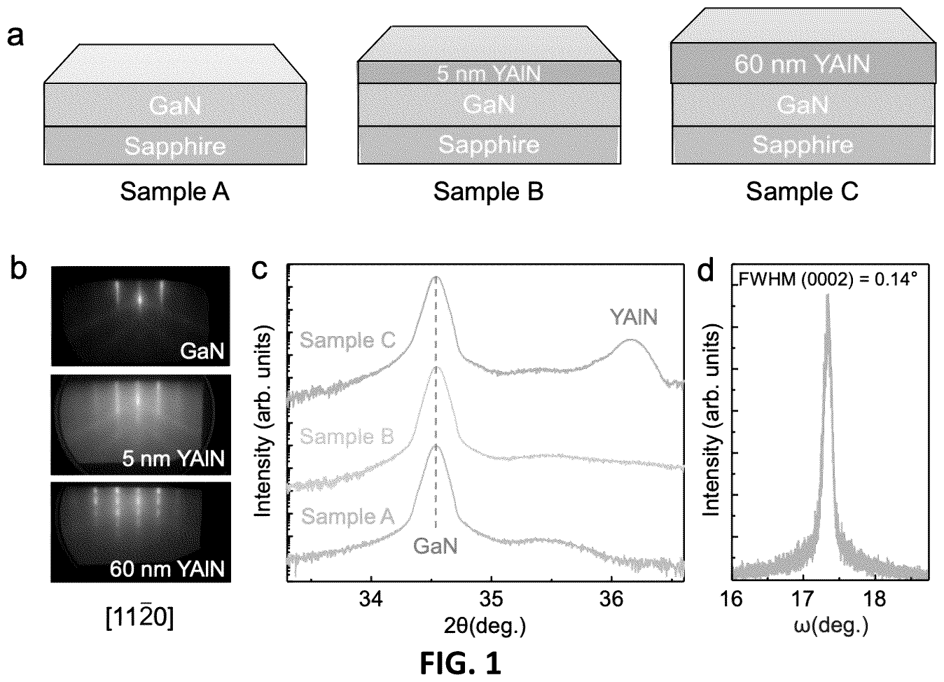

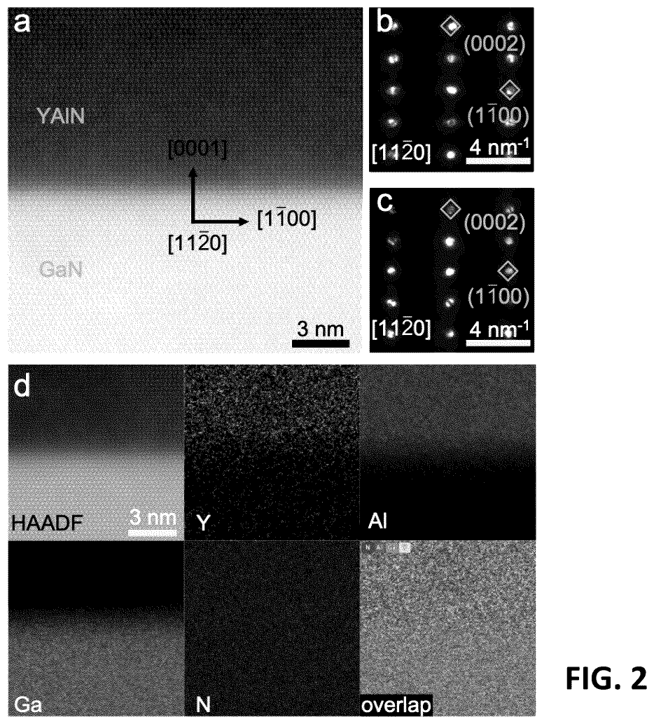

The band alignment between YAlN and III-nitride materials was determined as follows. Because direct measurement of the valence band discontinuity for heterojunction interfaces is difficult, three different samples, schematically shown in FIG. 1, part (a), were designed, epitaxially grown, and characterized. For these samples, the Y composition of YAlN was 10%. Because the mean free path of photoelectrons in XPS measurements is approximately 5-10 nm, the top layer is thin enough to ensure simultaneous collection of photoemission signals from both Y_{0.07}Al_{0.93}N and GaN layers. Thus, 5 nm Y_{0.07}Al_{0.93}N was grown on GaN as sample B for measuring the core level (CL) energy difference between each segment of the heterojunction. To collect XPS signals from the GaN and Y_{0.07}Al_{0.93}N layers independently, a layer is sufficiently thick to eliminate the influence of the underlying layer. Therefore, re-grown GaN and 60 nm Y_{0.07}Al_{0.93}N/GaN were used as sample A and sample C, respectively, for collecting the valence band maximum (VBM) and CL energy. The narrow and streaky patterns with clear Kikuchi lines captured in the RHEED patterns along <112̅0> for three samples after growth indicate that the surface of epitaxially grown Y_{0.07}Al_{0.93}N and GaN films are atomic-level smooth with single-crystalline wurtzite structure (FIG. 2, part (b)). FIG. 2, part (c), shows the X-ray diffraction (XRD) 2θ/ω scan result of the three samples. A characteristic diffraction peak for wurtzite Y_{0.07}Al_{0.93}N film is observed at 36.2° for sample C, while this peak is not seen for sample B due to its ultrathin thickness. The broad peak around 35.5° in sample A originates from the AlN buffer layer in the GaN/sapphire template. The material quality of the wurtzite Y_{0.07}Al_{0.93}N film is further studied through (0002) plane XRD rocking curve measurement. The full-width-half-maximum (FWHM) of the Y_{0.07}Al_{0.93}N film is 0.14°, which demonstrates that the crystal quality of the Y_{0.07}Al_{0.93}N film surpasses previously reported sputtered-grown YAlN films.

To determine the microstructural quality of the Y_{0.07}Al_{0.93}N/GaN interface, high-angle annular dark-field scanning transmission electron microscopy (HAADF-STEM) and corresponding EDS mapping were employed. FIG. 2, part (a), displays the cross-sectional HAADF-STEM image of the 60 nm Y_{0.07}Al_{0.93}N/GaN sample, emphasizing a sharp interface between the heterostructure and the well-aligned crystal lattices of Y_{0.07}Al_{0.93}N and GaN. This observation exemplifies the remarkable epitaxial quality of the heterostructure. Nanobeam electron diffraction patterns acquired from the YAlN and GaN layers are shown in FIG. 2, parts (b) and (c), respectively. These patterns confirm that the YAlN layer exhibits a single-phase wurtzite structure, as verified by the characteristic reciprocal lattice spacing ratio between the (0002) and (1120) plane reflections of the wurtzite crystal lattice. This finding indicates that the incorporation of yttrium atoms neither compromises the wurtzite structure nor introduces any intermetallic or rock salt phases. FIG. 2, part (d), presents the atomic-resolution HAADF-STEM image of the Y_{0.07}Al_{0.93}N/GaN interface and corresponding EDS mapping results. The presence of an atomically well-defined and sharp Y_{0.07}Al_{0.93}N/GaN interface is supported by the abrupt contrast change. The EDS maps for Y, Al, Ga, and N elements collectively demonstrate the uniform incorporation of yttrium atoms into the wurtzite crystal lattice.

The band offset of the Y_{0.07}Al_{0.93}N/GaN heterojunction was further analyzed using HR-XPS spectra collected from the three samples described previously. The methodology developed by Kraut et al. was used to determine the band alignment of the thin film heterostructure interfaces. This methodology involves measuring the difference between CL and VBM binding energy for each component of the heterostructure separately. Subsequently, by measuring the difference between the CLs in the heterostructure, the valence band offset (ΔEᵥ) at the Y_{0.07}Al_{0.93}N/GaN heterojunction interface was calculated as follows:

$$Δ {E}_{V} = ( {E}_{Al 2 p}^{YAlN} - {E}_{VBM}^{YAlN} ) - ( {E}_{Ga 3 d}^{GaN} - {E}_{VBM}^{GaN} ) + ( {E}_{Ga 3 d}^{YAlN / GaN} - {E}_{Al 2 p}^{YAlN / GaN} ) \qquad ( 1 )$$

where

$${E}_{Al 2 p}^{YAlN} and {E}_{Ga 3 d}^{GaN}$$

represent the CL energy of the thick Y_{0.07}Al_{0.93}N and thick GaN films, respectively.

$${E}_{VBM}^{YAlN} and {E}_{VBM}^{GaN}$$

are the VBMs binding energy of the thick Y_{0.07}Al_{0.93}N and GaN films, respectively.

$${E}_{Al 2 p}^{YAlN / GaN} - {E}_{Ga 3 d}^{YAlN / GaN}$$

represents the energy difference between the Al 2p and Ga 3d of the 5 nm Y_{0.07}Al_{0.93}N/GaN heterostructure. To determine the energy of the VBM, the linear portion of the low energy edge of the valence band is extrapolated to the spectral baseline.

The value of

$${E}_{VBM}^{YAlN} and {E}_{VBM}^{GaN}$$

of the thick Y_{0.07}Al_{0.93}N and thick GaN films were found to be 2.3 eV and 1.9 eV above the Fermi level, respectively. For

$${E}_{Ga 3 d}^{GaN}$$

of thick GaN film, there is only one peak located at 19.2 eV, which represents the Ga-N bonds. Consequently, for the thick GaN layer, the calculated binding energy difference between Ga 3d and the VBM is found to be 17.3 eV. The Al 2p CL spectra of thick Y_{0.07}Al_{0.93}N were deconvoluted using two peaks, formed from a 30:70 Gaussian-Lorentzian product with constrained FWHM on a Shirley background. It is worth mentioning that, although the samples were protected in vacuum immediately after removal from MBE chamber, surface oxidation cannot be completely avoided during the sample transfer process, due to the strong oxygen affinity of Y and Al elements. The peak located at 73.5 eV is assigned to the Al-N bonds and the AI-O bond appears at 75.5 eV. To accurately determine the band alignment of Y_{0.07}Al_{0.93}N/GaN heterojunction, the binding energy of the Al-N bond (73.5 eV) is chosen as

$${E}_{Al 2 p}^{YAlN} .$$

As such, the disparity between the binding energy of the Al-N 3d peak and the VBM was conclusively determined to be 71.2 eV. For the 5 nm Y_{0.07}Al_{0.93}N/GaN heterostructure, the single Al-N 2p peak is found to have a binding energy of 73.2 eV, while the Ga-N peak is located at 19.2 eV. The binding energy of Al 2p peak is shifted in the heterostructure compared to the thick Y_{0.07}Al_{0.93}N film, primarily due to the influence of the band bending at the heterostructure interface. Consequently, the energy separation between the Al 2p and Ga 3d peaks is calculated to be 54 eV. Using equation 1 above, the valence band offset of the Y_{0.07}Al_{0.93}N/GaN heterostructure is determined to be −0.1 eV.

To calculate the conduction band offset (ΔEc), the energy bandgaps of Y_{0.07}Al_{0.93}N obtained from the Tauc plot (E_{g}=5.7 eV) [49, 50] and GaN (E_{g}=3.4 eV) as well as the valence band offset (ΔE_{c}) are substituted into equation 2 below. As a result, the conduction band offset

$$Δ {E}_{C} = {E}_{g}^{YAlN} + Δ {E}_{V} - {E}_{g}^{GaN} \qquad ( 2 )$$

(ΔEc) is calculated to be 2.2 eV.

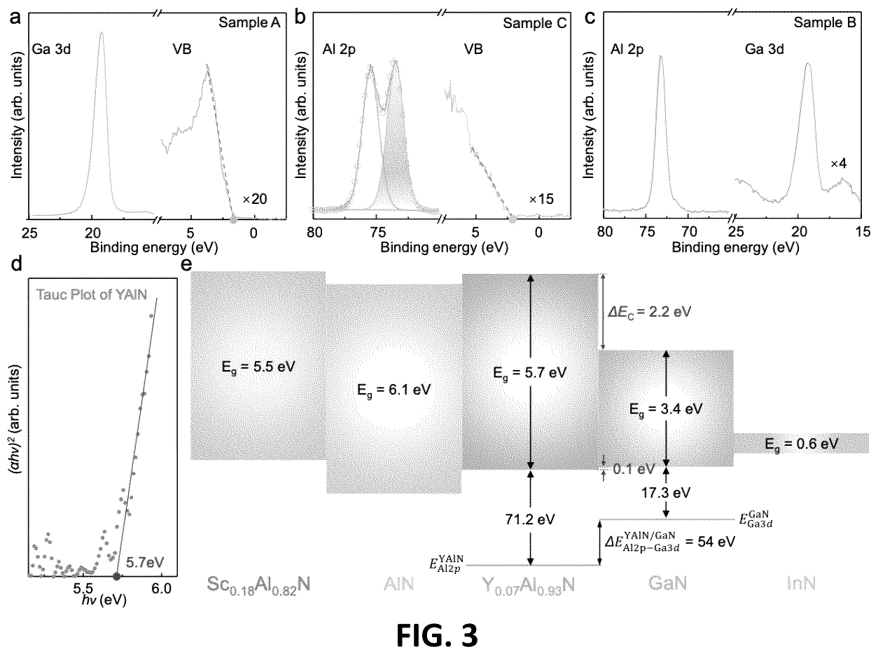

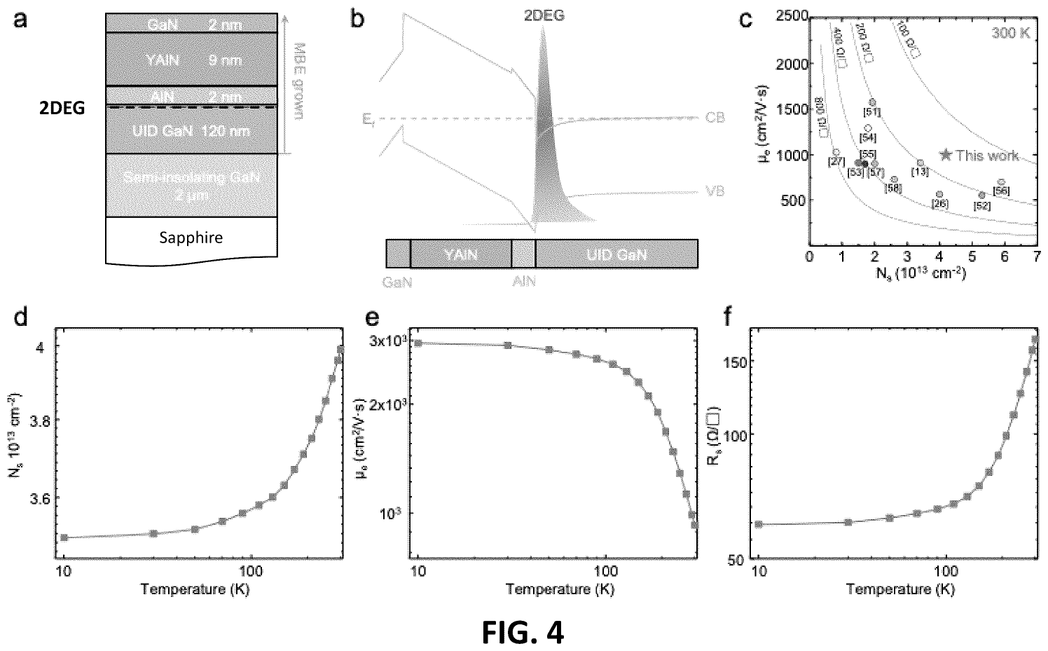

Based on the foregoing experimentally determined parameters, the Y_{0.07}Al_{0.93}N/GaN heterojunction exhibits a type-I band alignment, indicating that the heterojunction may be useful in numerous applications, including in optoelectronic devices such as light-emitting diodes (LEDs) and laser diodes (LDs). This type-I lineup behavior, together with the III-nitride capabilities of Y_{0.07}Al_{0.93}N/GaN, facilitates efficient electron-hole recombination in the active region, leading to high radiative recombination rates and efficiency. By integrating the band alignments of InN, GaN, AlN, and lattice-matched Sc_{0.18}Al_{0.82}N/GaN, the band alignment relationship of Y_{0.07}Al_{0.93}N with III-nitride materials is depicted in FIG. 3, part (d). The band alignments will be useful in a variety of electronic and optoelectronic devices, an example of which is described below in connection with FIG. 4.

Guided by the band alignments of Y_{0.07}Al_{0.93}N with III-nitride materials, a YAlN/AlN/GaN HEMT structure in accordance with one example was fabricated. FIG. 4, part (a), shows the schematic of the device structure, while FIG. 4, part (b), illustrates the energy band diagram of the YAlN/AlN/GaN HEMT device. A 9-nm-thick Y_{0.07}Al_{0.93}N layer was used as the barrier layer, while a 2 nm aluminum nitride (AlN) insertion layer was introduced to enhance channel mobility. The entire HEMT structure was completed with a 2 nm GaN cap layer, which served to prevent potential surface oxidation.

Room-temperature mobility measurements were conducted on the YAlN/AlN/GaN HEMT structure using a van der Pauw geometry on the YAlN/AlN/GaN HEMT structure, which revealed a mobility of 1000 cm²/Vs and a sheet electron concentration of 4.2×10¹³ cm². The resulting sheet resistance is as low as 148 Ω/□.

FIG. 4, part (c), compares the room temperature transport properties of the example YAlN/AlN/GaN HEMT structure with previously reported rare earth element-containing nitride epitaxial heterostructures. It is seen that the example structure has one of the best values reported thus far.

Temperature-dependent Hall effect measurements between 10 and 300 K were conducted. A minor monotonic decrease of the sheet carrier density to 3.5×10¹³ cm² at 10 K was observed, which is consistent with typical 2DEG behavior in which the sheet carrier density experiences only a slight freeze-out as the temperature decreases. Intriguingly, Hall mobility and sheet resistance display a pronounced temperature dependence, with p monotonically increasing to 2950 cm²/Vs (10 K) and Rs decreasing to 60.4Ω (10 K), which further corroborate the presence of a well-confined two-dimensional electron gas (2DEG). It is useful to highlight that the temperature dependence of electron transport characteristics in various temperature regimes appears to be influenced by distinct scattering mechanisms. By comparing the observed trends in temperature-dependent Hall effect measurements with the transport properties of previously reported ScAlN-based heterostructures, it is seen that interface roughness scattering dominates the transport properties at low temperatures, while the intrinsic scattering mechanism due to polar optical phonons prevails at higher temperature.

The excellent transport properties of the example YAlN-based HEMT device, in combination with the ferroelectric characteristics of the YAlN film (described below), render YAlN a useful material for high-frequency and high-power electronic applications. Moreover, YAlN can be lattice-matched to GaN, thereby enabling enhanced tunability of YAlN-based HEMT devices and other structures. The band alignments of Y_{0.07}Al_{0.93}N with III-nitride materials, together with temperature dependent transport properties of the YAlN/AlN/GaN heterostructure, establish the utility of integrating Y_{0.07}Al_{0.93}N into a number of III-nitride related applications, including power electronics, optoelectronics, artificial photosynthesis, and sensors.

Examples demonstrating ferroelectricity in wurtzite phase single crystalline YAlN films, grown on GaN using MBE, are now described. Single crystalline wurtzite YAlN examples with atomically smooth surface and sharp interfaces have been confirmed through a broad range of structural characterization techniques. The ferroelectric switching has been confirmed by several electrical characterization techniques, namely, P-E (polarization vs. electric field) and J-E (current density vs. electric field) loops, PUND (Positive-Up-Negative-Down) characteristics, and was further confirmed by butterfly shape capacitance-voltage (C-V) loops and polarity-sensitive wet etching. A coercive field of about 6 MV/cm with a high retainable remnant polarization of about 130 μC/cm² were measured for the epitaxially grown YAlN film with a Y content of 0.07, as determined by energy dispersive spectrometry (EDS). The disclosed examples establish the tuning of III-nitride semiconductors through Y alloying, thereby paving the way for a wide variety of multi-functional devices based on epitaxial nitride ferroelectrics.

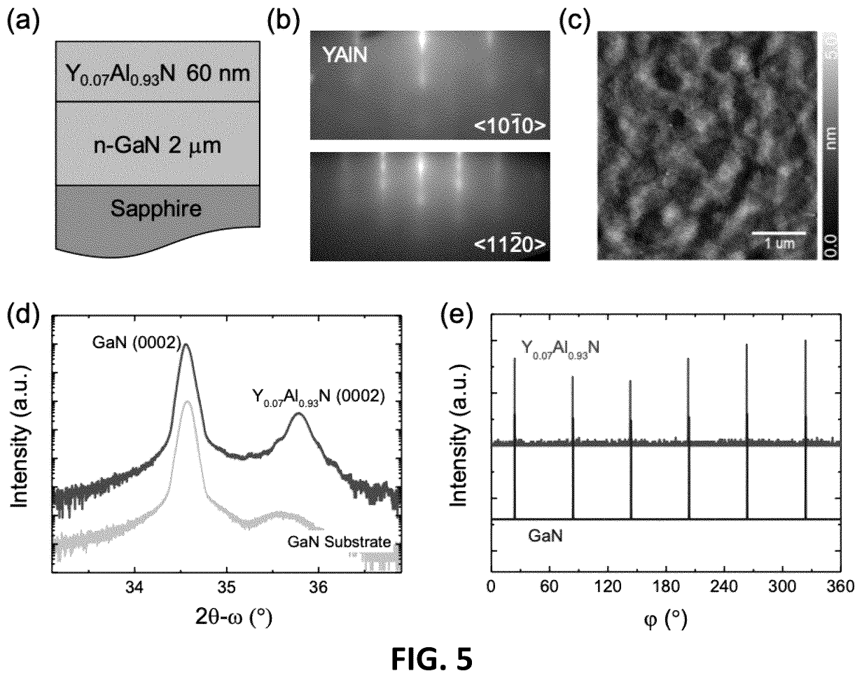

An example YAlN/n-GaN heterostructure (FIG. 5, part (a)) was grown by a Veeco GENxplor MBE system integrated with a Telemark electron beam (E-beam) evaporator. A Vecco RF UNI-Bulb plasma source was used to provide active nitrogen (N⁺, 6 N purity) species, whereas aluminum (Al, 6N5 purity), gallium (Ga, 7 N purity), and silicon (Si, 6 N purity) were supplied using Knudsen effusion cells. A 100 nm-thick Silicon doped GaN bottom contact layer was grown on GaN/sapphire templates with a dislocation density of 5×10⁸ cm⁻². The carrier concentration of the n-GaN layer was determined to be 5×10¹⁸ cm⁻³ from Hall measurement. Subsequently, 60 nm thick YAlN was grown under nitrogen rich conditions with a growth rate of about 2 nm/min. The evaporation rate of Y was monitored during the growth using an Inficon Guardian EIES controller.

Further details on the epitaxial growth conditions, procedures, and related parameters that may be used to form the ferroelectric films and heterostructures described herein are set forth in WO 2023/022768 (“Epitaxial Nitride Ferroelectronics”), International Application No. PCT/US23/13727 (“Epitaxial Nitride Ferroelectronic Devices” filed Feb. 23, 2023), P. Wang, et al., “Fully epitaxial ferroelectric ScAlN grown by molecular beam epitaxy,” Applied Physics Letters, vol. 118, p. 223504 (2021), D. Wang et al., “An Epitaxial Ferroelectric ScAlN/GaN Heterostructure Memory,” Advanced Electronic Materials, p. 2200005 (2022), and D. Wang, et al., “Fully epitaxial ferroelectric ScGaN grown on GaN by molecular beam epitaxy,” Appl Phys Lett 119 (11), 111902 (2021), the entire disclosures of which are hereby incorporated by reference.

An in-situ reflection high energy electron diffraction (RHEED) system was used to monitor the epitaxy process. A Rigaku SmartLab diffractometer with a Cu K_{α1} radiation X-ray source (1.5406 Å) was used to characterize the X-ray diffraction (XRD) of the epitaxially grown samples. High-angle annular dark-field imaging (HAADF) and annular bright field (ABF) scanning transmission electron microscope (STEM) images were collected using a Cs corrected JEOL 3100R05 microscope, and a Thermo Fisher Scientific Talos F200X S/TEM equipped with a Super-X EDS detector was used for elemental distribution analyses. The surface morphology was characterized ex-situ using a Bruker ICON AFM tool, and the Y composition and film thickness were determined using a Hitachi SU8000 scanning electron microscope (SEM) integrated with EDS. Circular 15-nm-Ti/100-nm-Al pads with diameters of 10-50 m were patterned on the top YAlN layer by standard photolithography process for the top-drive electrodes, whereas the underlying n-GaN layer was used as the bottom electrode. All the quasi-static electrical and ferroelectric measurements were performed by a B11500 semiconductor analyzer and a Radiant Precision Multiferroic II Ferroelectric Test System at room temperature.

RHEED patterns are shown in FIG. 5, part (b), along the [112̅0] and [101̅0]azimuths of the YAlN/GaN heterostructure. The observed RHEED patterns are bright, narrow and fairly streaky, indicating smooth surface morphology. The AFM image shown in FIG. 5, part (c), presents the surface morphology of the YAlN film. The R.M.S roughness acquired from the 4×4 μm² scan area is approximately 0.8 nm, which is much lower than the surface roughness values previously reported for sputtered YAlN thin films. No cracks were found on the YAlN surface. Moreover, clear atomic steps can be observed in the AFM image of the YAlN surface, thus indicating an extremely smooth surface morphology achieved by MBE growth.

FIG. 5, part (d), shows the (0002) plane XRD 2θ-ω scan results for the YAlN/GaN heterostructure along with a GaN template. The peak at 34.5° and 35.8° observed for the YAlN/GaN heterostructure are characteristic diffraction signatures from GaN and YAlN, respectively. No other diffraction peaks are observed in the long-range scan (20°-100°) from other asymmetric planes. A low-intensity bump in between the GaN and YAlN peaks arises from the underlying GaN/sapphire template. The full-width-half-maximum (FWHM) of (0002) plane XRC for the YAlN/GaN sample is obtained to be 324 arc sec, which is almost an order of magnitude less than previously reported values for sputtered YAlN films of a similar composition. Moreover, the (101̅2) plane XRC scan of YAlN results in an FWHM of 396 arc sec, further indicating the excellent crystalline quality of the epitaxially grown YAlN film. To evaluate the uniformity of in-plane orientation of the epitaxially grown YAlN thin film and the underlying GaN template, XRD phi (φ) scans were performed for both GaN and YAlN on the asymmetric (101̅2) plane using the same chi (χ=43.2) angle and corresponding 2e angles obtained from the (101̅2) 2θ-ω scan, as shown in FIG. 5, part (e). Six equidistant maxima for the YAlN film, with a separation of 60°, aligned with the phi peaks of the underlying GaN are observed, indicating the single crystalline nature and perfect epitaxial registry of YAlN with the underlying wurtzite GaN.

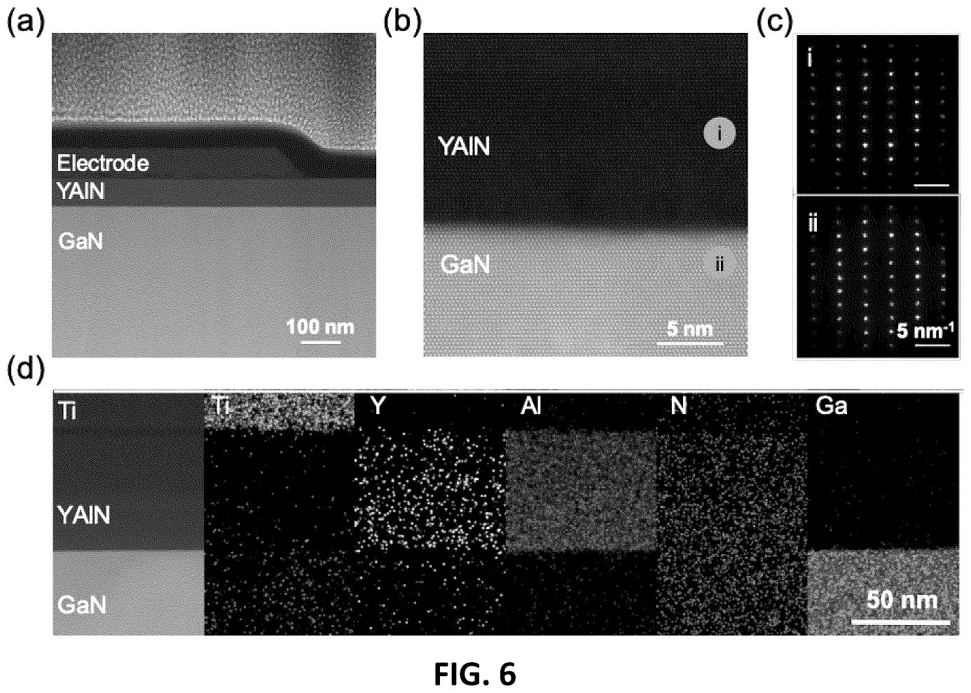

FIG. 6, part (a), depicts the cross-sectional HAADF STEM image of the YAlN/GaN heterostructure, with magnified image underneath the electrode and near the interface shown in FIG. 6, part (b), confirming uniform film thickness, well-aligned atoms and sharp interface. The nano-beam electron diffraction (NBED) patterns obtained from the YAlN layer and GaN layer along the [1120] zone-axis are presented in FIGS. 6, parts (ci) and (cii), respectively, revealing the wurtzite crystal structure of YAlN and GaN. FIG. 6, part (d), displays the element maps of the Ti/YAlN/GaN capacitor from EDS. A uniform incorporation of Y and Al can be observed along the growth direction of the YAlN thin film. By carefully measuring the NBED patterns, the lattice constants of YAlN are determined as a=0.3176 nm and c=0.5042 nm, corresponding to an internal parameter u of about 0.382, which is close to AlN due to the low Y composition. The measured in-plane lattice constant is quite close to the in-plane constant a of GaN (0.3181 nm in this study) within the accuracy of the measurement, indicating a coherent growth. The measured out-of-plane lattice constant c is slightly lower than theoretical prediction, which could be due to tensile strain. It should be noted that the region underneath the electrode, which has been subjected to ferroelectric switching for multiple times, shows no significant difference in contrast to the region without electrodes and maintains a good wurtzite structure, indicating that the ferroelectricity, which will be discussed later, stems from a wurtzite phase.

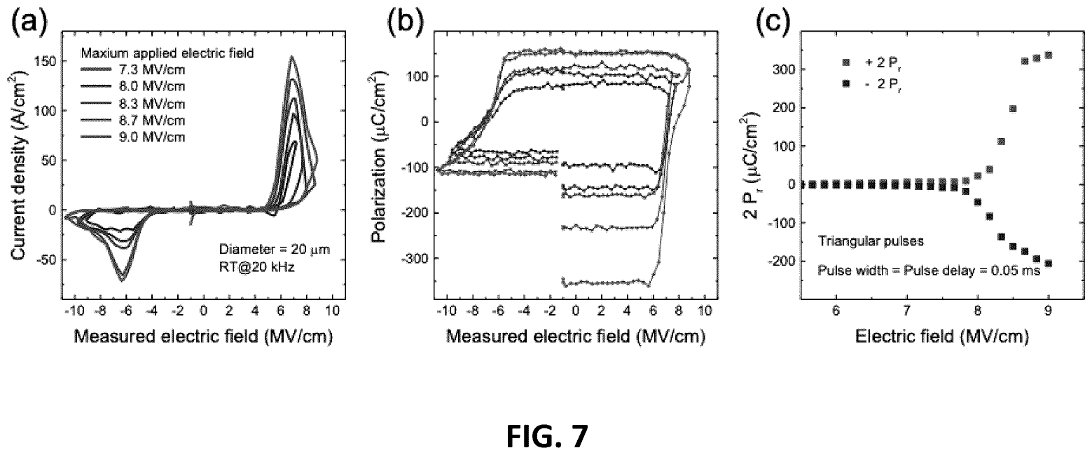

To examine the ferroelectricity in the fabricated devices, J-E loops, P-E loops and PUND measurements were carried out on standard capacitors driven from the top electrode with a diameter of 20 m. A series of unipolar triangular shape voltage sequences containing both non-switching and switching pulses were applied and the non-switching current were subtracted to better illustrate the switching characteristics. As shown in FIG. 7, part (a), distinct displacement current peaks can be observed, which is characteristic of ferroelectric switching. FIG. 7, part (b), displays the corresponding P-E loops. The measured polarization increases with increasing maximum bias voltage then slowly saturates for the negative branch. For the positive branch, the switchable polarization keeps increasing with maximum bias voltage, possibly due to enhanced dynamic leakage under high electric fields, similar to what has been observed in ScAlN based capacitors grown on GaN. To quantify the remnant polarization, PUND measurements were preformed and shown in FIG. 7, part (c). The clear saturation of polarization for both branches present strong evidence of ferroelectricity in the epitaxially grown YAlN thin film. An average remnant polarization of about 130 μC/cm² can be obtained, which is consistent with theoretical predictions for AlN related ferroelectrics. The similar remnant polarization value to those obtained for ScAlN alloys indicates that, in AlN-related wurtzite ferroelectrics, the polarization is dominated by the polarization of the host material, i.e., AlN. The asymmetry in the J-E loops, P-E loops and PUND results can be ascribed to the asymmetry in the contacts, i.e., Ti/Al for top electrode and n-GaN for bottom electrode. Noticeably, the measured coercive field is in the range of 6 MV/cm, which is comparable to Sc-doped or B-substituted AlN alloys with high Al compositions. This high coercive field could be useful for fabricating digital switching multilayers. With further optimization of Y content, a significantly reduced coercive field, compared to that of ScGaN, may be achieved.

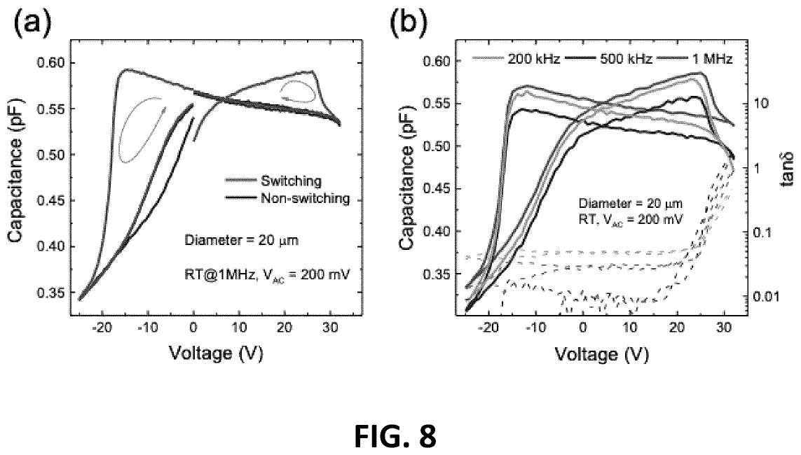

To corroborate the polarity switching of the epitaxial YAlN thin film, unipolar C-V loops were measured, as shown in FIG. 8, part (a). While the switching half loops show peaked capacitances and distinct hysteresis in a butterfly shape, the non-switching half loops are almost hysteresis-free and overlap with the backtrack of the switching loops, characteristic of ferroelectric materials. The estimated dielectric constant of the YAlN film is about 11.5, which is close to sputtered YAlN films with a similar Y composition. FIG. 8, part (b), further shows the frequency dependent C-V measurement results. Butterfly shaped C-V hysteresis loops can be observed under different measurement frequencies, and the extracted dielectric loss is less than 0.1 for most of the frequency range. The increase of dielectric loss at high positive bias voltages is attributed to the increased leakage current. The coercive field, determined by the peak position of the C-V loops, is about 4 MV/cm, which is lower than the values obtained from P-E loops due to the much slower scan rate during C-V measurements.

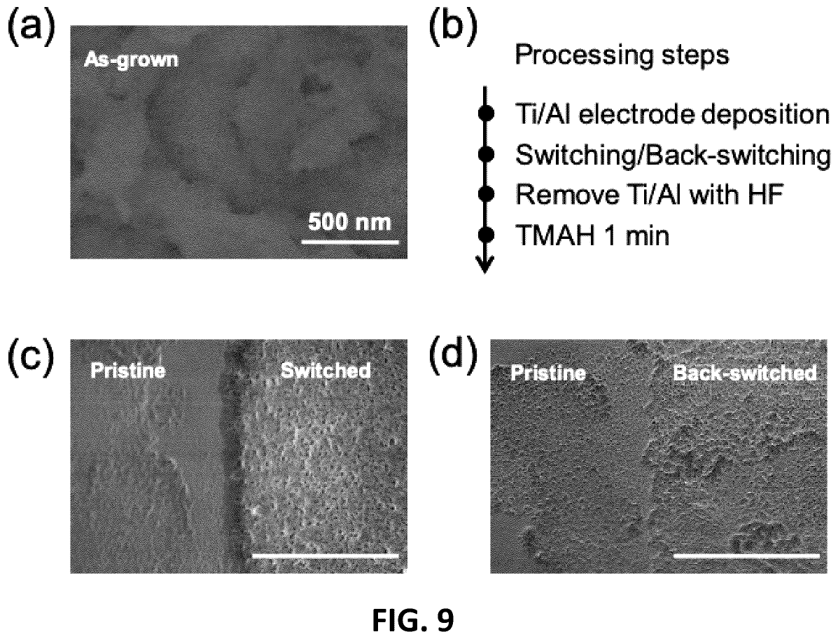

The polarity switching in the epitaxial YAlN film was further verified via polarity-sensitive wet etching. In this process, some capacitors were switched, while some were switched then switched back again. The electrodes were removed by hydrofluoric (HF) acid to expose the projected regions. The sample was then dipped into Tetramethylammonium hydroxide (TMAH) for 1 min for polarity-sensitive wet etching. As shown in FIGS. 9, parts (c) and (d), the switched regions were severely etched by TMAH, while the back-switched region and the as-grown region stay almost unaffected, consistent with previous studies on Sc and B alloyed AlN films. These results thus provide unambiguous evidence of ferroelectricity in epitaxial YAlN films.

The dielectric constant of the YAlN ferroelectric is on the lower side among all ferroelectrics, which may be useful for better electric field distribution control in multi-layer dielectric configurations and help reduce signal delay. The high coercive field is likely due to the low Y composition and may be utilized to design digital switching multilayers and other devices.

Described above are examples of heterostructures having high-quality, wurtzite phase, ferroelectric YAlN grown via plasma-assisted MBE. The epitaxially grown YAlN film exhibited ferroelectric switching behavior with a coercive field in the range of 4-6 MV/cm and switchable polarization of about 130 μC/cm², comparable to previously reported nitride ferroelectrics. The ferroelectricity has been further verified by C-V loops and polarization sensitive wet etching. The example nitride ferroelectrics may be used in a wide variety of electronic, optoelectronic, and piezoelectric devices.

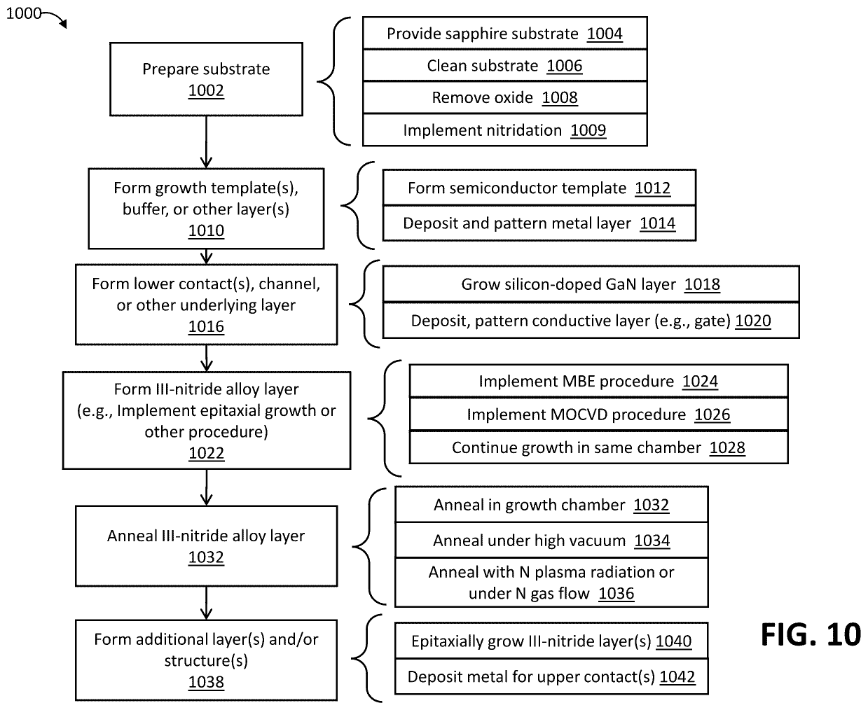

FIG. 10 depicts a method 1000 of fabricating a heterostructure having a wurtzite structure of an alloy of a III-nitride material with yttrium (Y) incorporated therein in accordance with one example. As described herein, the method 1000 is configured such that the wurtzite structure exhibits ferroelectric behavior. The heterostructure may form a device, or a part of a device, in which one or more layers or regions of the device exhibit the ferroelectric behavior. The method 1000 may be used to fabricate the examples of YₓAl₁₋ₓN films and layers described herein.

The method 1000 may begin with an act 1002 in which a substrate is prepared and/or otherwise provided. In some cases, the act 1002 includes providing a sapphire substrate in an act 1004. The sapphire substrate may have an on-axis, or off-axis, c-plane at the growth front. The act 1004 may include patterning or otherwise processing the substrate to establish an off-cut angle. The sapphire substrate may thus be or include off-cut sapphire. Additional or alternative patterning of the substrate may be used to configure the substrate to reduce defect formation in subsequently grown layers of the heterostructure and/or otherwise improve material quality therein. Such processing may also facilitate the formation of a heterostructure having alternating regions of metal- and nitrogen-polarity.

Alternative or additional substrate materials may be used, including, for instance, silicon, bulk GaN, bulk AlN, or other semiconductor material. Still other materials may be used, including, for instance, silicon carbide. The substrate may be cleaned in an act 1006. In some cases, a native or other oxide layer may be removed from a substrate surface in an act 1008. In the example of FIG. 10 (e.g., sapphire examples), the act 1002 may include implementing a nitridation procedure in an act 1009. Additional or alternative processing may be implemented in other cases, including, for instance, doping or deposition procedures. The substrate thus may or may not have a uniform composition. The substrate may be a uniform or composite structure.

In an act 1010, one or more growth templates, buffer, or other layers are formed. The layer(s) are thus formed on, or otherwise supported by, the substrate. The layer(s) may or may not be in contact with the substrate. In some cases, the layer(s) are composed of, or otherwise include, a semiconductor material. For instance, the act 1010 may include an act 1012 in which a semiconductor layer is formed. For example, a III-nitride layer, such as a GaN layer, may be grown or otherwise formed on the substrate. Other compound or other semiconductor materials may be used, including, for instance, AlGaN. The semiconductor layer(s) may be N-polar, metal-polar, or alternating or otherwise mixed polarity (e.g., periodically poled structures). The semiconductor layer(s) may form a part of the heterostructure underlying the ferroelectric layer to be grown. The semiconductor layer be undoped or doped (e.g., Si-doped). The act 1012 may thus be implemented before (e.g., in preparation for) implementing an epitaxial growth procedure in which a wurtzite structure is formed. The wurtzite structure may thus be formed on the semiconductor layer. The semiconductor layer may be configured or used as a growth template for the wurtzite structure and/or other elements of the heterostructure. In some cases, the act 1012 may include growing the semiconductor layer in an epitaxial growth chamber in which the epitaxial growth procedure for the wurtzite structure is implemented. As a result, the substrate may remain within, e.g., is not removed from, the epitaxial growth chamber between forming the semiconductor layer and implementing the epitaxial growth procedure for growing the wurtzite structure.

Alternatively or additionally, the act 1010 includes an act 1014 in which one or more metal or other conductive layers are deposited and patterned. For example, an aluminum layer may be deposited on a silicon substrate in preparation for the epitaxial growth of the wurtzite structure.

The method 1000 may include an act 1016 in which one or more contacts or other layers are formed. The layer(s) may form a part of the heterostructure underlying the ferroelectric layer to be grown. Examples of the underlying layer(s) include a lower or bottom contact of the heterostructure or a channel layer of the heterostructure. The nature of the underlying layer(s) may vary with the device being fabricated. The Si-doped layer may or may not be grown on top of the template or buffer layer formed in the act 1010. In the example of FIG. 10, the act 1016 includes growing a silicon-doped GaN layer in an act 1018. The Si-doped GaN layer may be N-polar or metal-polar. Other materials may be used. For instance, the underlying layer(s) may be composed of, or otherwise include, AlGaN, InAlN, InGaN, or InAlGaN. Still other materials may be used. For instance, a channel layer may be composed of, or otherwise include, other types of semiconductors, e.g., Ga₂O₃, diamond, Si, SiGe, GaAs, InGaAs, or InP, in addition to one or more of the above-referenced III-nitride alloys, Additional or alternative conductive structures, such as a gate structure, may be deposited and/or patterned in an act 1020.

In an act 1022, a non-sputtered epitaxial growth procedure is implemented at a growth temperature to form a wurtzite structure supported by the substrate. As described herein, the wurtzite structure is composed of, or otherwise includes, an alloy of a III-nitride material. For instance, the III-nitride material may be AlN. Additional or alternative III-nitride materials may be used, including, for instance, gallium nitride (GaN), indium nitride (InN), and their alloys. As also described herein, the epitaxial growth procedure is configured to incorporate yttrium (Y) into the alloy of the III-nitride material. The alloy may thus be YₓAl₁₋ₓN, for example. The composition of the alloy may vary. For instance, the alloy may include one or more additional group IIIB elements. In some cases, the act 1022 includes an act 1024 in which an MBE procedure is implemented. In other cases, an MOCVD or other non-sputtered epitaxial growth procedure is implemented in an act 1026.

The act 1022 may constitute a continuation, or part of a sequence, of growth procedures. The growth procedures may be implemented in a common, or same, growth chamber. The act 1022 may thus include an act 1028 in which epitaxial growth is continued in the same chamber in which one or more other layers of the heterostructure were grown. For instance, one or more of the growth template and the underlying semiconductor layer(s) formed in the acts 1010 and 1016 may be formed in the same chamber as the ferroelectric layer. Sequential layers of the heterostructure may thus be grown without exposure to the ambient. The quality of the interface between the layers may accordingly be improved.

The growth temperature may be at a level such that the wurtzite structure exhibits a breakdown field strength greater than a ferroelectric coercive field strength of the wurtzite structure. Ferroelectric switching and other behavior may thus be achieved.

The growth temperature is at a level lower than what would be expected given the III-nitride material. In some examples, the growth temperature level is significantly less than the temperature at which the III-nitride material would typically be grown. For instance, the growth temperature level may be such that attempts to grow a structure composed of the III-nitride material (i.e., without yttrium) at the growth temperature level would not be worthwhile. The resulting structure would be of such poor quality (e.g., possess far too many defects) to be useful. Growth of a single crystal of the scandium-including alloy (e.g., a monocrystalline layer of the alloy) at the growth temperature level may nonetheless be achieved. For example, in some cases, a YₓAl₁₋ₓN alloy may be epitaxially grown at a growth temperature of about 650 degrees Celsius despite that the corresponding (scandium-free) III-nitride material, AlN, is conventionally grown at much higher temperatures, e.g., about 1000 degrees Celsius. Conversely, attempts to grow AlN at about 650 degrees Celsius or lower would result in structures of such poor quality so as to be useless. In contrast, the epitaxially grown YₓAl₁₋ₓN layer grown at that low temperature is unexpectedly monocrystalline and of high quality.

Growth of the YₓAl₁₋ₓN layer at the conventional AlN growth temperature (and other temperatures above the upper bound) unexpectedly results in the formation of dislocations and/or other leakage paths in the YₓAl₁₋ₓN layer. With the leakage paths, the YₓAl₁₋ₓN layer has a breakdown field strength level too low (e.g., below the ferroelectric coercive field strength level). The layer accordingly does not exhibit ferroelectric behavior.

In some cases, the growth temperature may be about 650 degrees Celsius or less. The growth temperature may correspond with the temperature measured at a thermocouple in the growth chamber. The growth temperature at the epitaxial surface may be slightly different. The growth temperature is accordingly approximated via the temperature measurement at the thermocouple.

The upper bound of the growth temperature range may vary in accordance with the alloy and/or the epitaxial growth technique. For instance, in other cases, the upper bound on the growth temperature may be higher, such as about 680 degrees Celsius, or about 690 degrees Celsius. In still other cases, the upper bound may be lower, including, for instance, about 600 degrees Celsius or about 620 degrees Celsius.

At each level within the above-described ranges of suitable growth temperatures, the resulting wurtzite structure is monocrystalline. The resulting wurtzite structure is monocrystalline to a degree not realizable via, for instance, sputtering-based procedures for forming YₓAl₁₋ₓN layers. Such procedures are only capable of producing structures with x-ray diffraction rocking curve line widths on the order of a few degrees at best. In contrast, the structures grown by the disclosed methods exhibit x-ray diffraction rocking curve line widths on the order of a few hundred arc-seconds or less, well over an order of magnitude less. In this manner, leakage current paths are minimized or otherwise sufficiently reduced so that the resulting wurtzite structure has a suitably high breakdown field strength level, e.g., sufficiently greater than the ferroelectric coercive field strength.

The above-noted differences in crystal quality evidenced via x-ray diffraction rocking curve line widths may also be used to distinguish between monocrystalline and polycrystalline structures. As used herein, the term “polycrystalline” refers to structures having x-ray diffraction rocking curve line widths on the order of a few degrees or higher. As used herein, the term “monocrystalline” refers to structures having x-ray diffraction rocking curve line widths at least one order of magnitude lower than the order of a few degrees.

Comparing the wurtzite structures of the layers grown by MBE or other non-sputtered techniques (e.g., MOCVD or HVPE) with sputtering deposition techniques, the microstructure of the former techniques is more uniform with highly ordered stacking sequence of atoms. In sputter deposited layers, domains with cubic phase or domains with in-plane mis-orientation are readily observed. The existence of these mis-aligned domains suppresses the complete switching of polarization, and further results in the fast loss of polarization during fatigue testing. Regarding phase purity, the highly crystallographic orientation of layers grown by MBE or other non-sputtered techniques exhibits more repeatable ferroelectric switching, which is useful in a number of device applications.

The wurtzite structure of the ferroelectric layer may be nitrogen-polar (N-polar) or metal-polar. The polarity of an underlying layer formed in the act 1010 and/or the act 1016 may be used to establish the polarity of the ferroelectric layer formed in the act 1022. As described herein, the polarity of the underlying layer may, in turn, be established by a characteristic of the substrate. The polarity may continue across the interface between the underlying layer and the ferroelectric layer. Either N- or metal-polarity may thus persist as the composition changes from the underlying layer to the ferroelectric layer.

The wurtzite structure may then be annealed in an act 1030. The annealing may be implemented at a temperature greater than the growth temperature. In some cases, the annealing temperature falls in a range from about 700 Celsius to about 1500 degrees Celsius. Examples of films prepared with such annealing exhibited stable polarization switching with further reduced leakage current relative to non-annealed films. Film or device uniformity was also improved via the annealing, thereby further improving the polarization switching behavior of the ferroelectric Y-III-N alloys. The underlying mechanism for the improved performance and uniformity with annealing is attributed to the reduced threading dislocation density and defect density, which usually act as electric leakage paths. Such usefulness of the post-growth annealing is realized despite past concerns that high processing temperatures can lead to a loss of ferroelectricity.

Such post-growth high-temperature annealing of YₓAl₁₋ₓN may be performed in-situ in the same growth chamber (e.g., the same MBE chamber) in an act 1032. In other cases, the annealing is performed ex-situ in a chamber directed to annealing procedures.

The annealing process may be implemented under high vacuum in an act 1034 (e.g., in-situ in the growth chamber). In other cases, the annealing may be implemented either with nitrogen plasma radiation or under nitrogen gas flow in an act 1036.

The above-described annealing procedure may be implemented in connection with films grown under any of the above-described growth conditions. For instance, the annealing procedure may be implemented after growth under slightly to moderately N-rich conditions at a growth temperature below about 650 degrees Celsius. The annealing procedure may also be implemented after growth under unbalanced flux ratios (e.g., N-rich or extreme N-rich conditions) at growth temperatures above about 650 degrees Celsius.

The method 1000 may include an act 1038 in which one or more layers (e.g., semiconductor layers) are formed after growth of the wurtzite structure. As a result, the layer(s) may be in contact with the wurtzite structure. For instance, one or more III-nitride (e.g., GaN or AlGaN) or other semiconductor layers may be epitaxially grown in an act 1040. The act 1040 may be implemented in the same epitaxial growth chamber used to grow the wurtzite structure. As a result, the substrate (and heterostructure) is not removed from the epitaxial growth chamber between implementing the acts 1022 and 1038.

Alternatively or additionally, the act 1038 includes an act 1042 in which one or more metal or other conductive layers or structures are formed. The layers or structures may be deposited or otherwise formed. In some cases, the conductive structure is configured as an upper or top contact. For instance, the conductive structure may be a gate.

The method 1000 may include one or more additional acts. For example, one or more acts may be directed to forming other structures or regions of the device that includes the heterostructure. In a transistor device example, the regions may correspond with source and drain regions. The nature of the regions or structures may vary in accordance with the nature of the device.

The order of the acts of the method 1000 may differ from the example shown in FIG. 10. For example, the acts 1016, 1018, and 1020 in which contacts and/or other conductive structures formed may be implemented after the growth of the ferroelectric layer.

A number of different types of devices may be fabricated by the method 1000 of FIG. 10, and/or another method of fabricating a heterostructure having a wurtzite structure of an alloy of a III-nitride material with yttrium incorporated therein. For example, the ferroelectric YₓAl₁₋ₓN or other alloy of a III-nitride material may be useful in various types of nonvolatile memory devices (e.g., FeRAM, FeFET, FTJ, and FeSFET devices), various types of reconfigurable electronic and other devices (e.g., Fe-HEMT, Fe-capacitor, and SAW devices), various types of photodetection, photovoltaic and optoelectronic devices (e.g., self-driven photodetector and solar cell devices), and various homojunction devices (e.g., devices that use a laterally distributed charge plate to tune the Fermi level in adjacent layers). Still other types of devices may be fabricated, including, for instance, FE-based thin-film bulk acoustic wave resonators (FBAR) devices.

A number of example devices are now described. In each example, the device includes a substrate and a heterostructure supported by the substrate. The heterostructure includes a monocrystalline layer of an alloy of a III-nitride material. As described herein, the alloy includes yttrium. As also described herein, the monocrystalline layer exhibits a breakdown field strength greater than a ferroelectric coercive field strength of the monocrystalline layer. In some cases, the III-nitride material is aluminum nitride (AlN), but other III-nitrides may be used.

In some of the devices described below, the device also includes a semiconductor layer disposed between the substrate and the heterostructure. The semiconductor layer may include a further III-nitride material, such as GaN. In some cases, the semiconductor layer is in contact with the heterostructure. The epitaxial growth of the layers may result in a high quality interface between the layers. Alternatively or additionally, the device also includes a metal or other conductive layer disposed between the substrate and the heterostructure. The metal layer may be in contact with the heterostructure, examples of which are described below.

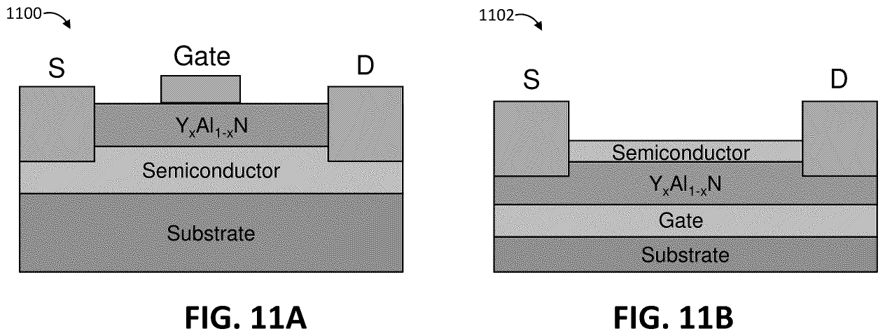

FIGS. 11A and 11B depict examples of FeFET memory devices 1100, 1102. In each device 1100, 1102, a ferroelectric YₓAl₁₋ₓN layer is disposed between a gate electrode and a source-drain conduction region. The ferroelectric layer provides a reversible electrical state for a transistor of the device. The large remnant electrical field polarization in the ferroelectric YₓAl₁₋ₓN layer retains the state of the transistor (e.g., on or off) in the absence of any electrical bias to form a single transistor nonvolatile memory. In some cases, bulk and/or other semiconductor channel layers are composed of, or otherwise include, GaN or silicon, or two-dimensional materials like MoS₂ or graphene. In each device 1100, 1102, the FeFET memory device 1100, 1102 may include a heterostructure including, for instance, the ferroelectric YₓAl₁₋ₓN or other alloy of a III-nitride material, along with one or more layers of a III-nitride semiconductor, such as AlN, as the gate dielectric and barrier. The substrate supporting these layers and structures of the devices may be composed of, or otherwise include, for instance, GaN or silicon. The control terminal or gate may be disposed above or below the heterostructure as shown.

Other types of memory devices include one transistor one capacitor (1T-1C) FeRAM devices. For example, a FeRAM device may include a MIM ferroelectric capacitor composed of, or otherwise including, Al, YₓAl₁₋ₓN, and Al supported by a pre-processed silicon or GaN substrate.

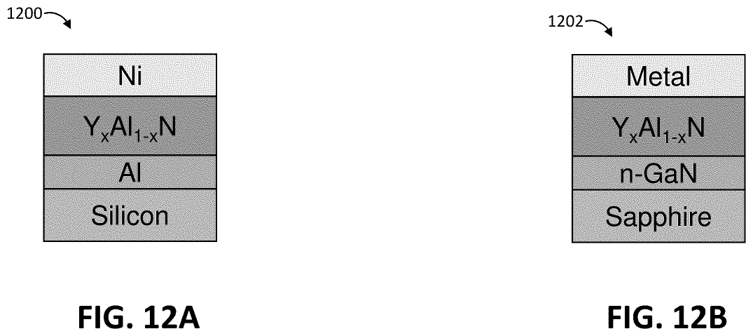

FIGS. 12A and 12B depict examples of FTJ memory devices 1200, 1202. In the example device 1200, an epitaxially grown ferroelectric layer is disposed between metal layers (e.g., nickel and aluminum layers). In the other example device 1202, the ferroelectric layer is disposed between a III-nitride semiconductor layer (e.g., n-type doped GaN) and a metal layer. Other metal-Fe (insulator)-metal and metal-(insulator)-Fe-(insulator)-semiconductor configurations may be used. In these example devices 1200, 1202, the YₓAl₁₋ₓN or other alloy provides the ferroelectricity and tunes the ON/OFF current/resistance ratio as a memorizer readout.

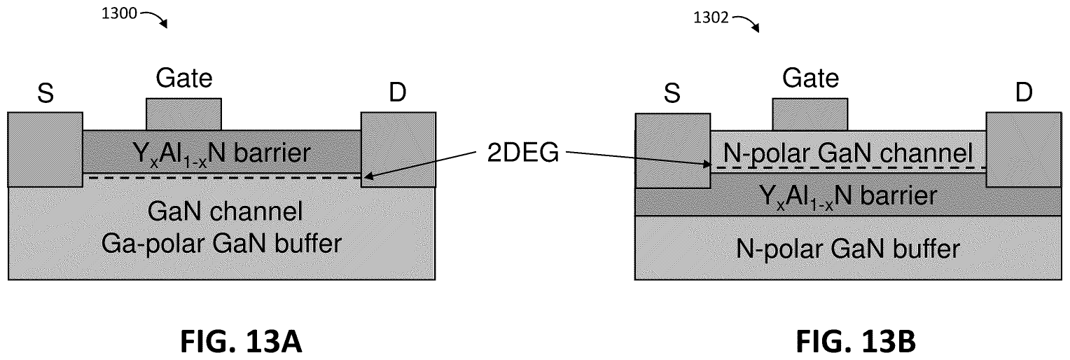

FIGS. 13A and 13B depict examples of metal-polar and N-polar Fe-HEMT devices 1300, 1302, respectively. In these two examples, each of the devices 1300, 1302 includes a heterostructure composed of, or otherwise including, a stack of ferroelectric YₓAl₁₋ₓN, channel, and buffer layers. The order or arrangement of the layers varies as shown between the metal-polar and N-polar examples. The heterostructure may include additional, fewer, or alternative layers. For instance, the N-polar buffer layer shown in the device 1302 of FIG. 13B may be grown on an additional, underlying Si-doped N-polar III-nitride layer, such as an Si-doped, N-polar GaN layer.

The heterostructure may be grown on a bulk or other region composed of, or otherwise including, a III-nitride semiconductor material, such as GaN. One or more of the III-nitride semiconductor layers may be doped, e.g., Si or otherwise n-type doped. Other III-nitride semiconductors may be used, including, for instance, AlGaN, InGaN, and InAlGaN as described herein. A switchable two-dimensional electron gas (2DEG) heterojunction may thus be formed due to the strong spontaneous polarization in the YₓAl₁₋ₓN layer during operation as shown. A thin AlN layer may be inserted between the YₓAl₁₋ₓN and channel layers to enhance carrier mobility.

Still other types of transistor devices may utilize the epitaxially grown ferroelectric layers described herein, including, for instance, N-polar bottom-gated and gate-recessed transistor devices, both with and without a gate oxide layer.

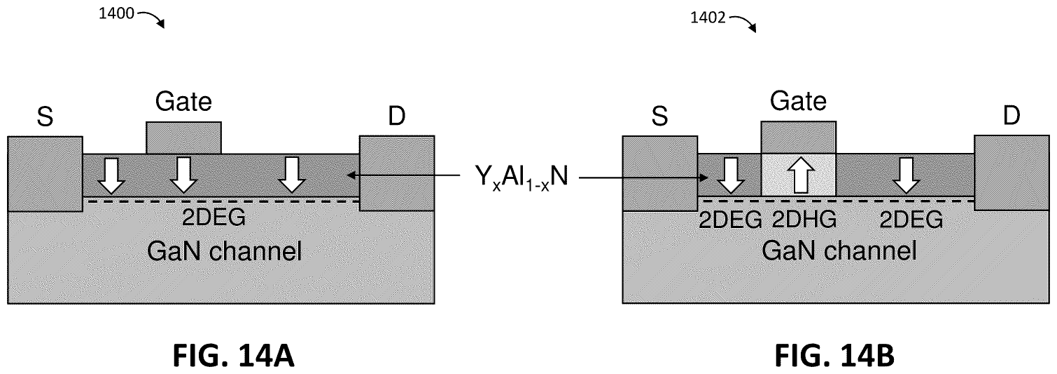

FIGS. 14A and 14B depict examples of reconfigurable Fe-HEMT devices 1400, 1402. In these example, each of the devices 1400, 1402 includes a heterostructure with a ferroelectric YₓAl₁₋ₓN layer. As shown in FIG. 14A, the heterostructure may include a stack of ferroelectric YₓAl₁₋ₓN and channel layers, in which the polarization of the ferroelectric YₓAl₁₋ₓN layer can be switched. Alternatively, the heterostructure may be configured such that a 2DHG or depletion region underlying the polarization switched region is formed, as shown in FIG. 14B. The disclosed devices include still other types of reconfigurable Fe-HEMT devices, including, for instance, Fe-HEMT devices including the N-polar structure depicted in FIG. 13B.

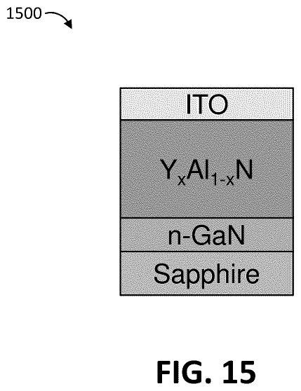

FIG. 15 depicts an example of a photovoltaic device 1500 in which a ferroelectric layer is integrated into a heterostructure having one or more III-nitride layers between electrodes of the device. In the example shown, the heterostructure includes an n-type GaN layer adjacent to, and in contact with a YₓAl₁₋ₓN layer. An indium tin oxide (ITO) layer establishes one of the electrodes (e.g., a transparent cathode or anode) of the device. Photon-generated carriers in the YₓAl₁₋ₓN layer are separated and collected by the polarization-induced electric field. The heterostructure may be supported by a sapphire or other substrate.

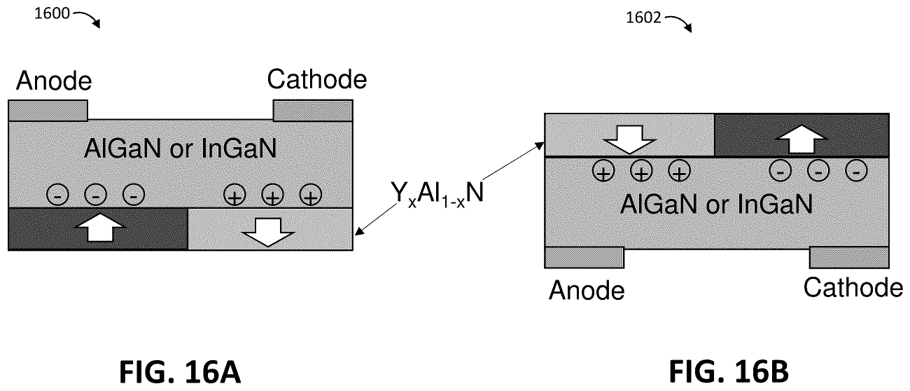

FIGS. 16A and 16B depict further examples of photovoltaic devices 1600, 1602. In each example, the polarization in a ferroelectric layer attracts electron/hole charges to different regions, thereby creating a built-in electric field in a light-absorption layer and helping to separate and collect the photon-generated carriers.

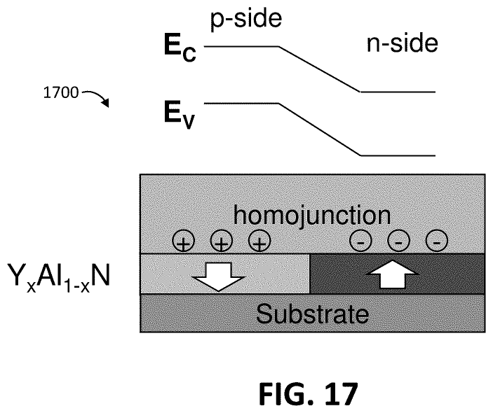

FIG. 17 depicts an example of a homojunction device 1700 having a ferroelectric layer adjacent a channel layer or region. The modulated polarization in the ferroelectric layer attracts electrons and holes in opposite directions, thereby forming a lateral homo p-n junction inside the channel material. The homojunction may be formed in semiconductors such as GaN, Si and two-dimensional materials.

Described above are example devices and structures that utilize ferroelectric switching in yttrium (Y) doped nitride semiconductors. The disclosed devices may include single-crystalline, wurtzite YAlN films, such as Y_{0.07}Al_{0.93}N films, epitaxially grown on GaN/sapphire templates by plasma-assisted molecular beam epitaxy. The disclosed devices provide example uses of the ferroelectric YAlN films in various III-nitride based electronic, piezo-electronic and optoelectronic devices.

The term “about” is used herein in a manner to include deviations from a specified value that would be understood by one of ordinary skill in the art to effectively be the same as the specified value due to, for instance, the absence of appreciable, detectable, or otherwise effective difference in operation, outcome, characteristic, or other aspect of the disclosed methods and devices.

The present disclosure has been described with reference to specific examples that are intended to be illustrative only and not to be limiting of the disclosure. Changes, additions and/or deletions may be made to the examples without departing from the spirit and scope of the disclosure.

The foregoing description is given for clearness of understanding only, and no unnecessary limitations should be understood therefrom.

What is claimed is:

1. A device comprising:
a substrate; and
a heterostructure supported by the substrate, the heterostructure comprising:
an alloy layer comprising an alloy of a III-nitride material; and
a III-nitride semiconductor layer adjacent the alloy layer;
wherein:
the alloy comprises yttrium; and
a heterointerface between the alloy layer and the III-nitride semiconductor layer has a Type-I band alignment.

2. The device of claim 1, wherein the alloy layer is monocrystalline.

3. The device of claim 1, wherein the alloy layer is wurtzite phase.

4. The device of claim 1, wherein the alloy layer is ferroelectric.

5. The device of claim 1, wherein the alloy layer is positioned in the heterostructure as a gate dielectric layer.

6. The device of claim 1, wherein the alloy layer is positioned in the heterostructure as a barrier layer.

7. The device of claim 1, wherein the III-nitride semiconductor layer comprises GaN.

8. The device of claim 1, wherein the alloy has an yttrium composition of about 10% or less.

9. The device of claim 1, wherein the alloy has an yttrium composition between about 7% and about 10%.

10. The device of claim 1, wherein the ferroelectric III-nitride alloy layer comprises YAlN.

11. The device of claim 1, wherein the alloy layer is supported by the III-nitride semiconductor layer.

12. A device comprising:
a substrate; and
a heterostructure supported by the substrate, the heterostructure comprising:
an alloy layer comprising an alloy of a III-nitride material;
wherein:
the alloy comprises yttrium; and
the alloy has an yttrium composition of about 10% or less.

13. The device of claim 12, wherein the alloy layer is monocrystalline.

14. The device of claim 12, wherein the alloy layer is ferroelectric.

15. The device of claim 12, wherein the alloy layer is positioned in the heterostructure as a gate dielectric layer.

16. The device of claim 12, wherein the alloy layer is positioned in the heterostructure as a barrier layer.

17. The device of claim 12, wherein the heterostructure comprises a III-nitride semiconductor layer in contact with the alloy layer.

18. The device of claim 17, wherein the III-nitride semiconductor layer comprises GaN.

19. The device of claim 17, wherein the III-nitride semiconductor layer comprises AlN.

20. The device of claim 12, wherein the ferroelectric III-nitride alloy layer comprises YAlN.

21. The device of claim 12, wherein the yttrium composition is between about 7% and about 10%.

22. A high electron mobility transistor (HEMT) device comprising:
a substrate; and
a heterostructure supported by the substrate, the heterostructure comprising:
a barrier layer comprising an alloy of a III-nitride material, the alloy comprising yttrium;
a channel layer positioned relative to the barrier layer to define a junction at which a charge carrier sheet is disposed, the channel layer comprising a first III-nitride semiconductor material; and
an insertion layer disposed between the barrier layer and the channel layer, the insertion layer comprising a second III-nitride semiconductor material;
wherein a band gap difference between the first and second III-nitride semiconductor materials enhances mobility of the charge carrier sheet.

23. The HEMT device of claim 22, wherein the heterostructure further comprises a III-nitride semiconductor cap layer adjacent the barrier layer.

24. The HEMT device of claim 22, wherein the second III-nitride semiconductor material comprises AlN.
